(19) United States
(12) Patent Application Publication
(10) Pub. No.: US 2014/0167210 A1
(43) Pub. Date: Jun. 19, 2014

(54) SEMICONDUCTOR STRUCTURE AND FABRICATION METHOD

(71) Applicant: Semiconductor Manufacturing International Corp., Shanghai (CN)

(72) Inventor: DANIEL HU, Shanghai (CN)

(73) Assignee: Semiconductor Manufacturing International Corp., Shanghai (CN)

(21) Appl. No.: 13/897,360

(22) Filed: May 18, 2013

(30) Foreign Application Priority Data
Dec. 18, 2012 (CN) 201210553015.1

(51) Int. Cl. H01L 29/06; H01L 21/762

(52) U.S. Cl. CPC H01L 29/06; H01L 21/76224
USPC 257/506; 438/424

(57) ABSTRACT

Various embodiments provide a semiconductor structure and fabrication method. An exemplary semiconductor structure can include a semiconductor substrate having an isolation trench formed in the semiconductor substrate. A first barrier layer can be disposed on a bottom surface and a sidewall of the isolation trench. A light absorption layer can be disposed at least on a surface portion of the first barrier layer over the bottom surface of the isolation trench. A second barrier layer can fill the isolation trench to form an isolation structure in the semiconductor substrate. The isolation structure can have a top surface flushed with or over a top surface of the semiconductor substrate.

### CROSS-REFERENCES TO RELATED APPLICATIONS

This application claims the priority to Chinese Patent Application No. CN201210553015.1, filed on Dec. 18, 2012, which is incorporated herein by reference in its entirety.

### FIELD OF THE INVENTION

The present disclosure generally relates to the field of semiconductor manufacturing technology and, more particularly, relates to a semiconductor structure and methods for making the same.

### BACKGROUND

During semiconductor integrated circuit manufacturing, photolithography is often used to define regions for certain processes. A photolithography process includes first forming a photoresist (PR) layer on a semiconductor substrate; exposing and developing the PR layer to form a patterned PR layer to expose a surface of the semiconductor substrate to be processed; and then using the patterned PR layer as a mask to process the semiconductor substrate by an etching process, an ion implantation process, or other suitable processes.

FIGS.1-4 depict a process for forming well-regions using a photolithography process in a front end of line (FEOL) during semiconductor device manufacturing. In FIG. 1, a semiconductor substrate 100 is provided to include an active region 100a and other regions 100b. A shallow trench isolation (STI) structure 101 is formed between the active region 100a and any of the other regions 100b. Materials used for the semiconductor substrate 100 may be silicon, germanium-silicon, silicon carbide, gallium arsenide, etc. Materials used for the STI structures may be silicon oxide.

In FIG. 2, a PR layer 102 is formed on top surfaces of the semiconductor substrate 100 and the STI structures 101. In FIG. 3, the PR layer 102 is exposed and developed to form a photolithographic pattern 103 to expose a surface of the active region 100a. In FIG. 4, the PR layer 102 containing the formed photolithographic pattern 103 is used as a mask for an ion implantation to form a well region 104 in the active region 100a.

The formed well region 104, however, often does not have dimensions as originally designed for the well region. This is because dimensions of the photolithographic pattern 103 formed as depicted in FIGS. 1-4 are often different from its originally designed dimensions.

### BRIEF SUMMARY OF THE DISCLOSURE

The disclosure provides a semiconductor structure and fabrication method such that the formed photolithographic pattern has dimensions as originally designed.

According to various embodiments, there is provided a semiconductor structure. The semiconductor structure can include a semiconductor substrate including an isolation trench, a first barrier layer, a light absorption layer, and a second barrier layer. The first barrier layer can be disposed on a bottom surface and a sidewall of the isolation trench. The light absorption layer can be disposed at least on a surface portion of the first barrier layer over the bottom surface of the isolation trench. The second barrier layer can fill the isolation trench to form an isolation structure including the second barrier layer, the light absorption layer, and the first barrier layer in the semiconductor substrate. The isolation structure can have a top surface flushed (or coplanar) with or over a top surface of the semiconductor substrate.

According to various embodiments, there is also provided a method for forming a semiconductor structure. In this method, an isolation trench can be formed in a semiconductor substrate and a blocking layer can be formed on a surface of the semiconductor substrate to expose the isolation trench. A first barrier layer can be formed on a bottom surface and a sidewall of the isolation trench and on the blocking layer. A light absorption layer can be formed at least on a surface portion of the first barrier layer over the bottom surface of the isolation trench. A second barrier layer can be formed to fill the isolation trench to form an isolation structure in the semiconductor substrate. The second barrier layer can have a top surface flushed with or over a top surface of the semiconductor substrate.

As disclosed herein, an isolation trench can be filled with barrier layer(s) containing a light absorption layer to form an isolation structure used to isolate an active region from other regions in the semiconductor substrate. The light absorption layer can absorb light incident on the isolation structure, including at least a first and a second barrier layer, and can absorb light reflected at an interface between the semiconductor substrate and the isolation structure (e.g., in particular, the first barrier layer). When subsequently exposing and developing a photolithography (PR) layer, over the semiconductor substrate and the isolation structure, to form a patterned PR layer, multiple reflections of the incident light at the interface between the first barrier layer and the semiconductor substrate can be prevented from exiting from the first barrier layer to avoid undesired excessive exposure to the PR layer from underneath of the PR layer. Because undesired excessive exposure to the PR layer is avoided, dimensions of the photolithographic pattern in the PR layer can then be controlled as desired, e.g., as originally designed. In this manner, when the patterned PR layer is used as a mask for an ion implantation or other processes to form structures such as a well region in the semiconductor substrate, dimensions of these structures (e.g., the well region) can be achieved as originally designed.

Other aspects of the present disclosure can be understood by those skilled in the art in light of the description, the claims, and the drawings of the present disclosure.

### BRIEF DESCRIPTION OF THE DRAWINGS

FIGS. 1-4 depict a conventional method for forming a well region using a photolithography layer as a mask;

FIG. 5 depicts excessive exposure of a patterned PR layer when forming a well region;

FIG. 6 depicts formation of an anti-reflective layer under a PR layer when a well region is formed;

FIGS. 7-12 are schematics showing a semiconductor structure at various stages during its formation in accordance with various disclosed embodiments;

FIGS. 13-18 are schematics showing another semiconductor structure at various stages during its formation in accordance with various disclosed embodiments; and

FIG. 19 depicts a flow diagram for an exemplary method for forming a semiconductor structure in accordance with various disclosed embodiments.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

When forming a well region in a semiconductor substrate by a photolithography processes, the formed photolithographic pattern may have dimensions inconsistent with its original design. The formed well region may thus have dimensions different from the original design of the well region.

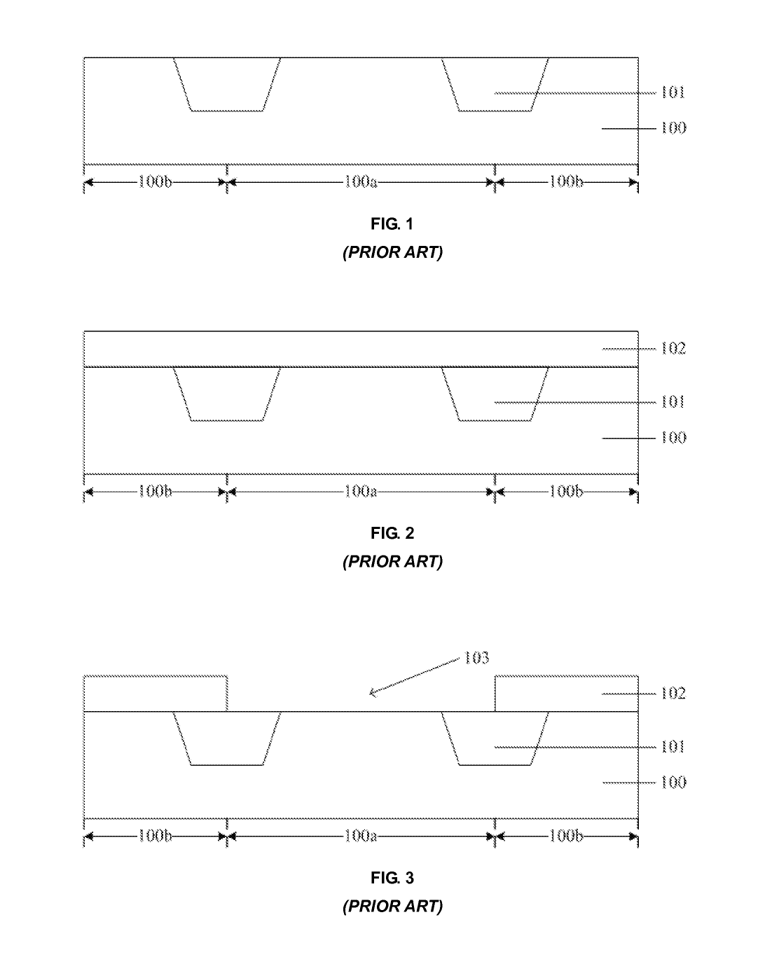

Based on the structures shown in FIGS. 1-4 and referring to FIG. 5, it is discovered that an interface 105 between the semiconductor substrate 100 and the STI structure 101 can server as a reflective mirror when the PR layer 102 is exposed to form photolithographic patterns therein. The reason may be that the STI structure 101 is made of a material including transparent silicon oxide with an extinction coefficient of k=0, while the semiconductor substrate 100 is made of a material such as silicon, silicon-germanium, silicon carbide or gallium arsenide, which may be opaque. During the exposure process of the PR layer 102, an incident light may be reflected from the interface 105 from underneath to a bottom of the PR layer 102, causing undesirable excessive exposure from the underneath to the PR layer 102. Thus, after exposure and development processes, the formed photolithographic pattern 103 in the PR layer 102 may have dimensions inconsistent with its original design.

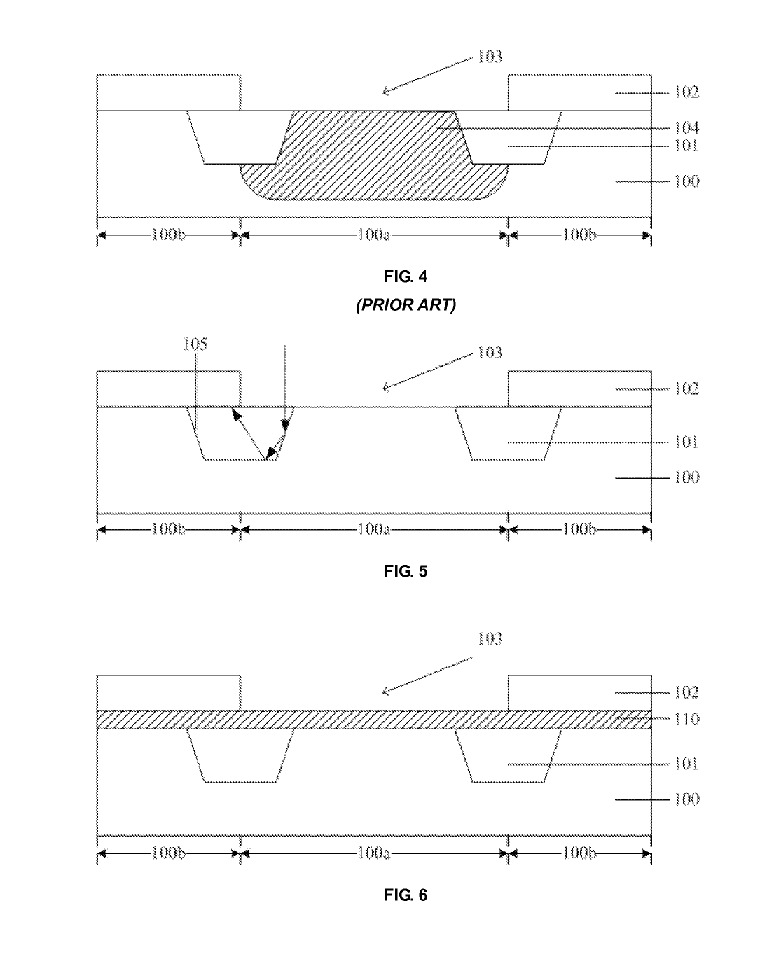

Additionally, the reflected light from the interface 105 is affected by a tilt angle of the interface 105 and the depth of the STI structure 101, and is related to a distance between the PR layer 102 and the active region 100a (and/or the other regions 100b). As a result, when the PR layer 102 is formed to cover a portion of the STI structure 101, the photolithographic pattern 103 may have dimensions that are different from the original design by from about 0 nm to about 100 nm. Once the PR layer 102 containing the photolithographic pattern 103 is used as a mask for an ion implantation in the semiconductor substrate 100 to form the well region 104 as shown in FIG. 4, the well region 104 may have undesired dimensions that are different from its original design. This affects device performance of the resultant semiconductor device.

As design area shrinks for the semiconductor devices, critical dimensions (CD) of the semiconductor devices become smaller and control of the CD becomes stricter in order to ensure the device performance of the semiconductor devices. There is a need to solve this and other problems to precisely control dimensions of the photolithographic pattern in the PR layer and to reduce dimensional differences between the formed photolithographic pattern and the original design for the photolithographic pattern, when using a patterned PR layer as the mask to form a well region.

In FIG. 6, a bottom anti-reflective coating (BARC) 110 is formed under the PR layer 102. The BARC 110 is made of a material including titanium nitride, silicon nitride, and organic anti-reflection coating. However, a portion of the BARC 110 associated with the remaining PR layer 102 (not including the photolithographic pattern 103) has to be etched away, prior to forming the well region 104 in the semiconductor substrate 100 by ion implantations. Such etching process may damage the surface of the semiconductor substrate 100. Device performance of the subsequently-formed semiconductor device may be impacted due to existence of the BARC 110.

As disclosed herein, a light absorption layer is formed within a trench isolation to form an isolation structure in a semiconductor substrate. The light absorption layer can absorb light incident on the isolation structure and can absorb light reflected from an interface between the isolation structure and the semiconductor substrate. Such light absorption layer can prevent a PR layer formed over the semiconductor substrate from being overly-exposed when patterning the PR layer. In this case, because the PR layer is not overly exposed, dimensions of the formed patterns in the PR layer can be controlled as designed. A well region formed there-from can thus have controlled dimensions, e.g., as originally designed.

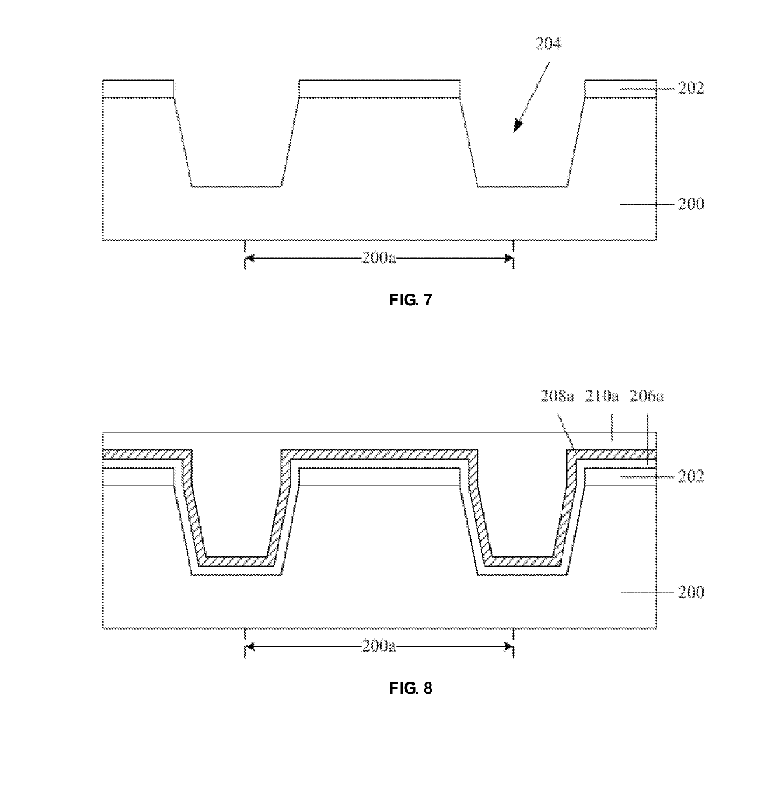

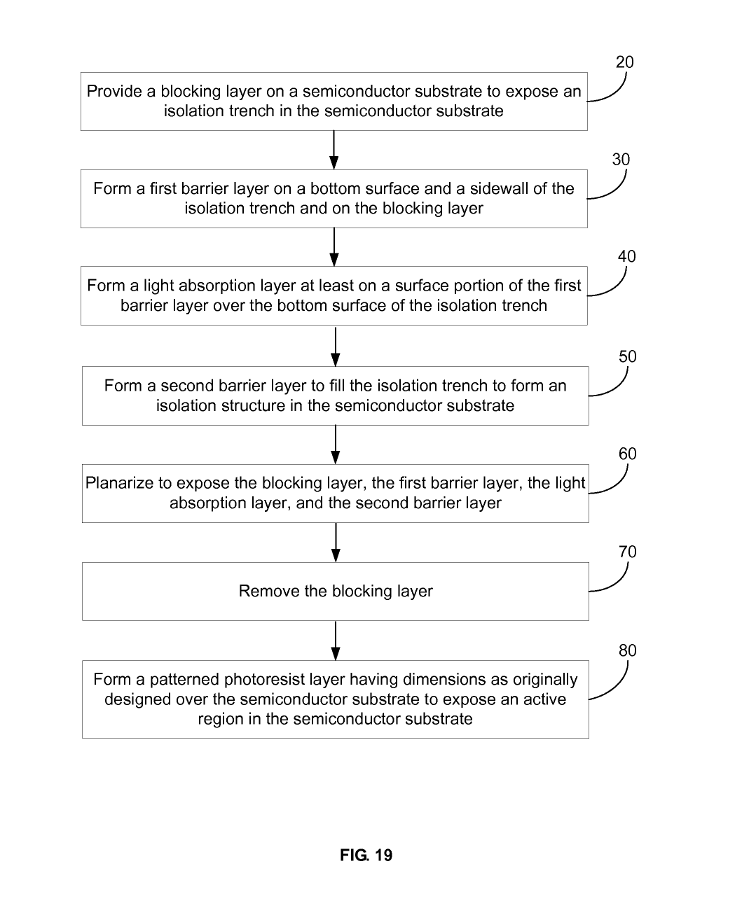

FIG. 19 depicts a flow diagram for an exemplary method for forming a semiconductor structure, while FIGS. 7-12 depict an exemplary semiconductor structure at various stages during its formation in accordance with various disclosed embodiments.

In Step 20 of FIG. 19 and referring to FIG. 7, a semiconductor substrate 200 is provided to include one or more isolation trenches 204. An active region 200a is defined between the two neighboring isolation trenches 204. The material(s) used for the semiconductor substrate 200 can be, for example, silicon, silicon-germanium, silicon carbide, insulating silicon compound, and/or other compounds in Group III-V (e.g., silicon nitride, gallium arsenide, etc.).

In subsequent processes, the active region 200a can be used to form a MOS device and/or any other suitable semiconductor active devices by forming a patterned PR layer to expose the active region 200a in the semiconductor substrate 200. For example, a well region may first be formed in the active region 200a, e.g., by a doping process such as an ion implantation process.

A blocking layer 202 can be disposed on surface of the semiconductor substrate 200 on both sides of the isolation trench 204. The material used for the blocking layer 202 can be, for example, silicon nitride. The blocking layer 202 can be used to define the position of the isolation trench 204 during formation of the isolation structures. In a subsequent formation of barrier layer(s), the blocking layer 202 can be used as a protection layer, e.g., in an exemplary process of chemical mechanical polishing (CMP), to effectively protect the surface of the underlying semiconductor substrate 200 from being damaged, such that the subsequently-formed semiconductor device can have reduced defects and improved device performance.

The isolation trenches 204 shown in FIG. 7 can be formed by a process including, for example, providing a semiconductor substrate 200; forming a blocking layer material (not shown) on the semiconductor substrate 200; and etching the blocking layer material to form openings through the entire thickness of the blocking layer material to form the blocking layer 202 that is patterned. The openings formed in the patterned blocking layer 202 can have a position corresponding to the position of the isolation trench(es) 204 to be subsequently formed. The patterned blocking layer 202 having through openings can be used as a mask to etch the semiconductor substrate 200 to form the isolation trench(es) 204 in the semiconductor substrate 200. Neighboring isolation trenches 204 can then define the active region(s) 200a in the semiconductor substrate 200. In various embodiments, the blocking layer 202 can be formed by, e.g., a chemical vapor deposition, a physical vapor deposition, or other suitable processes.

In other embodiments, prior to forming the blocking layer 202, a padding layer, such as an oxide padding layer (not shown in FIG. 7), may be formed or deposited on the semiconductor substrate 200 to enhance bonding between the semiconductor substrate 200 and the blocking layer 202 formed on the oxide padding layer. The blocking layer 202 can thus provide a better protection to the semiconductor substrate 200. In various embodiments, the oxide padding layer may be deposited by, e.g., a chemical vapor deposition process, and the oxide padding layer may be formed of silicon oxide.

Referring to FIG. 8, a first barrier layer 206a (e.g., in Step 30 of FIG. 19), a light absorption layer 208a (e.g., in Step 40 of FIG. 19), and a second barrier layer 210a (e.g., in Step 50 of FIG. 19) can be formed on the entire surface of the structure shown in FIG. 7. These layers can be sequentially formed on each surface of the bottom and sidewalls of the isolation trenches 204 and the blocking layer 202. The second barrier layer 210a can be formed over the light absoption layer 208a, which can be formed over the first barrier layer 206a. The second barrier layer 210a can have a top surface flushed with or over a top surface of the blocking layer 202.

In various embodiments, the first barrier layer 206a can be formed or deposited by a chemical vapor deposition process and the material used for the first barrier layer 206a can be transparent silicon oxide with a thickness of about 1 nm to about 50 nm having an extinction coefficient of about 0.

In various embodiments, the light absorption layer 208a can be formed or deposited by a chemical vapor deposition process, and the material formed thereof can be, for example, an anti-reflective inorganic material including silicon nitride, silicon oxynitride, silicon carbon, and/or silicon oxide. The light absorption layer 208a can have a thickness of about 5 nm to about 50 nm. The light absorption layer 208a can have a refractive index of about 1.5 to about 2.5 and an extinction coefficient of about 0.3 to about 2. The light absorption layer 208a can absorb light with a wavelength of about 193 nm to about 248 nm. In one embodiment, the refractive index of the light absorption layer 208a can be adjusted by adjusting the percentage of dopants therein, such as nitrogen and/or carbon dopants, to meet specific technical requirements.

In various embodiments, the second barrier layer 210a can be the same as the first barrier layer 206a and can be formed using a same process. The second barrier layer 210a can have a thickness of about 250 nm to about 1000 nm. The top surface of the second barrier layer 210a is not lower than the top surface of the blocking layer 202 to ensure a subsequent, complete filling of the second barrier layer 210a in the isolation trenches 204.

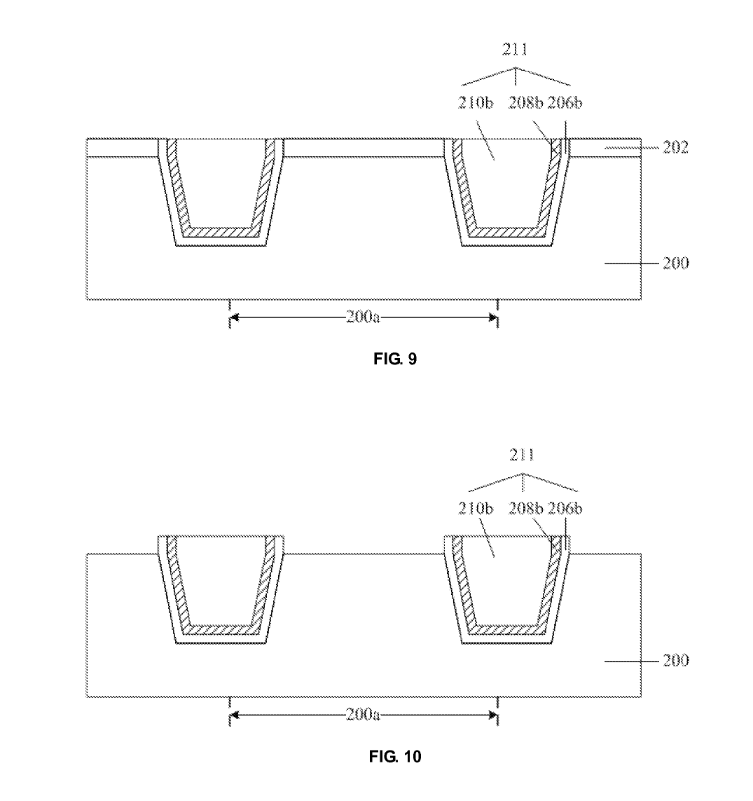

In Step 60 of FIG. 19 and referring to FIG. 9, a planarization process such as a chemical mechanical polishing (CMP) process can be used to remove portions of the second barrier layer 210a, the light absorption layer 208a, and the first barrier layer 206a to expose the blocking layer 202, the first barrier layer 206b, the light absorption layer 208b, and the second barrier layer 210b. By the planarization process, an isolation structure 211 as shown in FIG. 9 can be formed including the barrier layer 206b, the light absorption layer 208b, and the second absorption layer 210b in the semiconductor substrate 200. The light absorption layer 208b can be separated (e.g., isolated) from the semiconductor substrate 200 by the first barrier layer 206b to avoid direct contact between the light absorption layer 208b and the semiconductor substrate 200. This is because such direct contact there-between can affect isolation effect of the isolation structure 211.

In one embodiment, the light incident on the second barrier layer 210b can be absorbed by the light absorption layer 208b. In addition, because of a small thickness of the first barrier layer 206, a bottom surface of the light absorption layer 208b can be in proximity or sufficiently close to the interface between the first barrier layer 206b and the semiconductor substrate 200. The light incident on the first barrier layer 206 may be reflected at this interface and such reflected light can be absorbed by the light absorption layer 208b due to the thin first barrier layer 206b. Multiple reflections of the incident light (on the first barrier layer 206b) at the interface between the first barrier layer 206b and the semiconductor substrate 200 can be prevented from exiting from the first barrier layer 206 and from exposing to the PR layer 212a formed over the semiconductor substrate 200.

In other embodiments, to enhance bonding between the first barrier layer 206a and the semiconductor substrate 200, an oxide padding layer can be formed on the bottom surface and the sidewalls of the isolation trenches 204 prior to forming the first barrier layer 206a. In this case, the first barrier layer 206a is then formed on the oxide padding layer. In various embodiments, the oxide padding layer can be formed by a process, e.g., a thermal oxidation process.

In Step 70 of FIG. 19 and referring to FIG. 10, the blocking layer 202 can be removed, e.g., by a wet etching or a dry etching. In some cases, the wet etching can be used due to its process simplicity and due to less damage generated to the semiconductor substrate 200.

In some embodiments when the oxide padding layer is formed between the semiconductor substrate 200 and the blocking layer 202, the oxide padding layer may be removed following the removal of the blocking layer 202. For example, a dry etching or a wet etching can be used to remove such oxide padding layer. When the wet etching is used, hydrofluoric acid solution can be used.

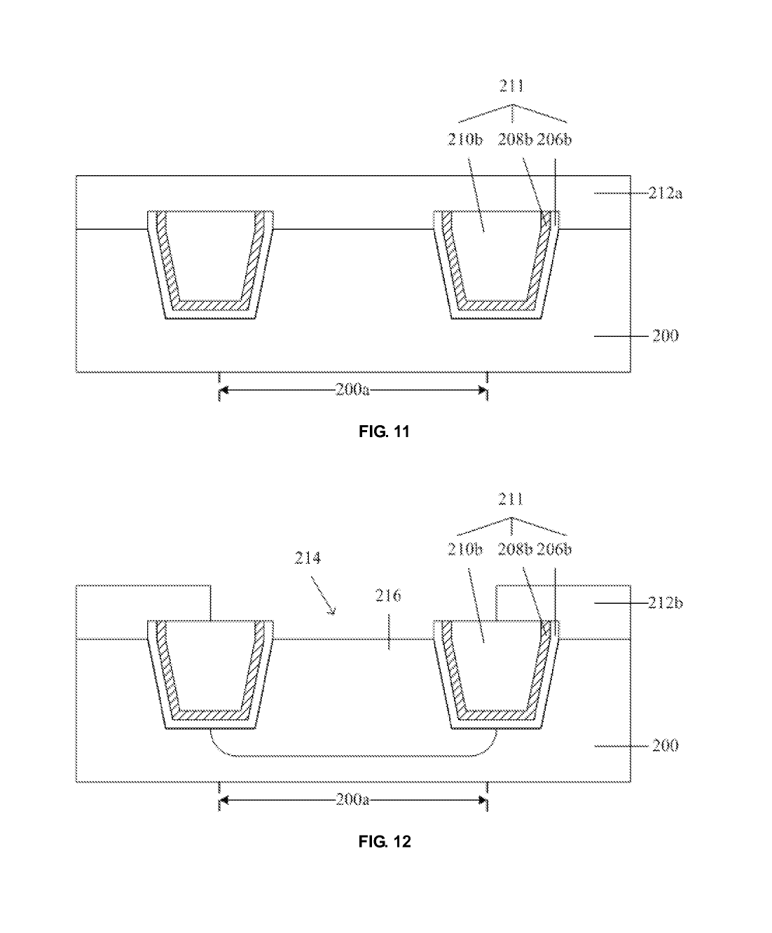

In Step 80 of FIG. 19 and referring to FIG. 11, a PR layer 212a is formed on the exposed surface of the structure shown in FIG. 10, i.e., on top surfaces of the semiconductor substrate 200 and the isolation structure 211. The PR layer 212a can have a thickness of about 40 nm to about 2000 nm. The PR layer 212a can be formed by a process, e.g., a spin coating process having a speed of about 300 rpm to about 4000 rpm and at a temperature of about 20+ C. to about 25° C. After the coating process, the PR layer can be heat treated for about 20 seconds to about 200 seconds at a temperature of about 50° C. to about 200° C., and then cooled down to the room temperature to form the PR layer 212a as shown in FIG. 11.

Still in Step 80 of FIG. 19 and referring to FIG. 12, a photolithographic pattern 214, e.g., an opening, is formed in the PR layer 212a to expose a top surface of the active region 200a in the semiconductor substrate 200 to form a patterned PR layer 212b. The patterned PR layer 212b can be formed by, e.g., exposure and development processes.

It is found impossible to expose only the portion of the PR layer 212a on the active region 200a due to limitation to alignment accuracy of existing lithography processes. It is thus hard to precisely expose the active region 200a in the semiconductor substrate 200 after the PR development. To ensure a complete exposure of the active region 200a in the semiconductor substrate 200, in addition to conducting an exposure to the portion of the PR layer 212a on the top surface of the active region 200a, portions of the PR layer 212a over the top surface of the isolation structure 211 that is adjacent to the active region 200a can be exposed during the exposure process.

During the exposure process of the PR layer 212a to form the patterned PR layer 212b, the absorption layer 208b located between the first barrier layer 206b and the second barrier layer 210b can absorb light incident on the top surface of the isolation structure 211 and light reflected from the interface between the isolation structure 211 and the semiconductor substrate 200. As such, the excessive exposure to the PR layer of the reflected light from underneath the PR layer is prevented. That is, the PR layer is exposed as desired without having undesired excessive exposure from the reflected light or any other possible light. Dimensions of the photolithographic pattern 214 formed in the PR layer 212b can then be precisely controlled, e.g., as originally designed.

Still in FIG. 12, the patterned PR layer 212b is used as a mask to perform, e.g., an ion implantation process, to form a well region 216 in the active region 200a of the semiconductor substrate 200. Depending on the types of MOS device to be formed, ion conductivity types for the ion implantation can be determined in the active region 200a. For example, when an NMOS device is to be formed in the active region 200a of the semiconductor substrate 200, P-type ions such as boron, boron difluoride, etc. can be implanted in the active region 200a. In another example, when a PMOS device is to be formed in the active region 200a of the semiconductor substrate 200, N-type ions such as phosphorus, arsenic, etc. can be implanted in the active region 200a.

In other embodiments, a protection layer (not shown) may be formed on surface of the active region 200a prior to the ion implantation into the active region 200a of the semiconductor substrate 200. Such protection layer can protect the surface of the active region 200a during the ion implantation. In one embodiment, the material used for the protection layer can be silicon oxide, and a thermal oxidization process can be used to form the protection layer.

In this manner, because the light incident on the surface of the first barrier layer 206b and the light reflected from the interface between the first barrier layer 206b and the semiconductor substrate 200 can be absorbed by the light absorption layer 208b, excessive exposure to the PR layer 212a from underneath the PR layer 212a can be effectively avoided. Therefore, the dimensions of the lithographic pattern 214 formed in the PR layer 212b can be precisely controlled, e.g., as originally designed. Further, the subsequently formed well region 216 can have dimensions as originally designed. Device performance of the subsequently-formed semiconductor device can be ensured.

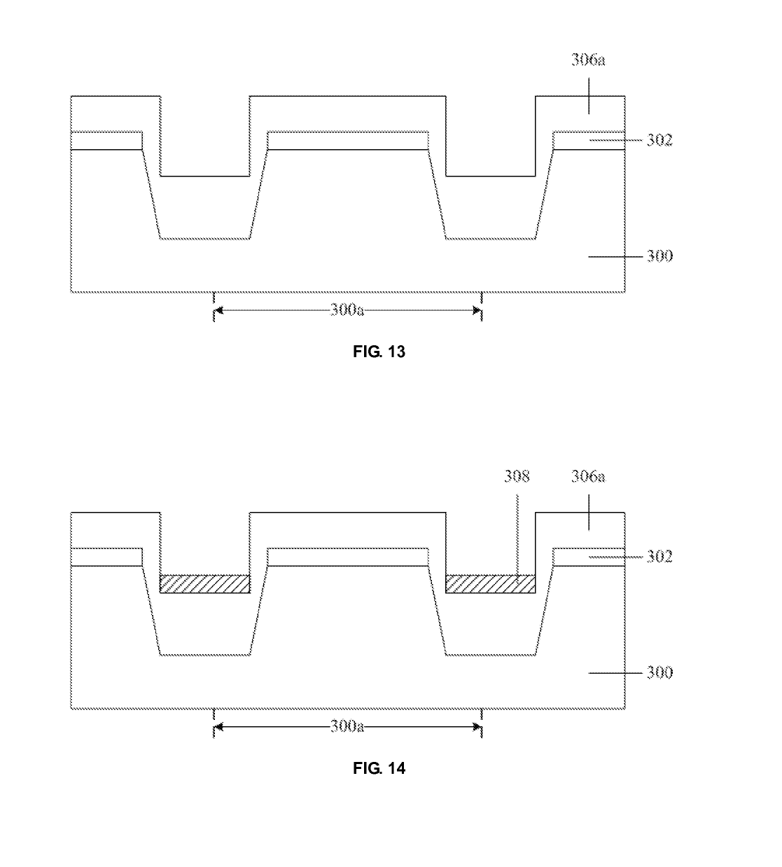

While FIG. 19 depicts a flow diagram for an exemplary method for forming a semiconductor structure, FIGS. 13-18 depict another semiconductor structure at various stages during its formation in accordance with various disclosed embodiments.

In Step 20 of FIG. 19 and referring to FIG. 13, a semiconductor substrate 300 can be provided including isolation trenches for defining an active region 300a there-between in the semiconductor substrate 300. A blocking layer 302 is formed on the semiconductor substrate 300 that are on both sides of the isolation trench. In various embodiments, the materials and formation processes used for the semiconductor substrate 300 can be the same as for the semiconductor substrate 200. The materials and formation processes used for the blocking layer 302 can be the same as for the blocking layer 202. The materials and formation processes used for the isolation trench of FIG. 13 can be the same as for the isolation trench 204.

In Step 30 of FIG. 19 and still referring to FIG. 13, a first barrier layer 306a can be formed on an entire surface of the semiconductor structure as shown in FIG. 12. For example, the first barrier layer 306a can be formed on a bottom surface and sidewalls of the isolation trench and on the top surface of the blocking layer 302. In one embodiment, the material used for the first barrier layer 306a can be transparent silicon oxide having a thickness of about 1 nm to about 50 nm and having an extinction coefficient k of about 0. In various embodiments, a chemical vapor deposition process can be employed to form the first barrier layer 306a.

In Step 40 of FIG. 19 and referring to FIG. 14, a light absorption layer 308 is formed on a surface portion of the first barrier layer 306a over the bottom surface of the isolation trench. The top surface of the light absorption layer 308 is lower than the top surface of the semiconductor substrate 300. In various embodiments, the formation method, material, thickness, refractive index, extinction coefficient, the absorbed light wavelength, etc. of the light absorption layer 308 can be the same as for the light absorption layer 208a/208b as disclosed herein.

The light absorption layer 308 can be formed by, for example, first depositing a light absorption layer material on the first barrier layer 306a (e.g., and/or to fill the isolation trench having the first barrier layer 306a). In various embodiments, the light absorption layer material can include a portion disposed over the isolation trench and having a top surface no lower than the top surface of the first barrier layer 306a that is on the blocking layer 302. A planarization process is then used to expose the first barrier layer 306a on the blocking layer 302. Following the planarization process, a wet etching process is applied to the remaining light absorption layer material such that the top surface of the light absorption layer material is lower than the top surface of the blocking layer 302 to form the light absorption layer 308 as shown in FIG. 14.

For example, the light absorption layer material can be formed by a chemical vapor deposition, and the thickness of the light absorption layer material can be about 200 nm to about 500 nm. Planarization can be performed by a chemical mechanical polishing process. The wet etching can use a wet etching solution including a hot phosphoric acid solution. The light absorption layer 308 can have a thickness of about 5 nm to about 50 nm.

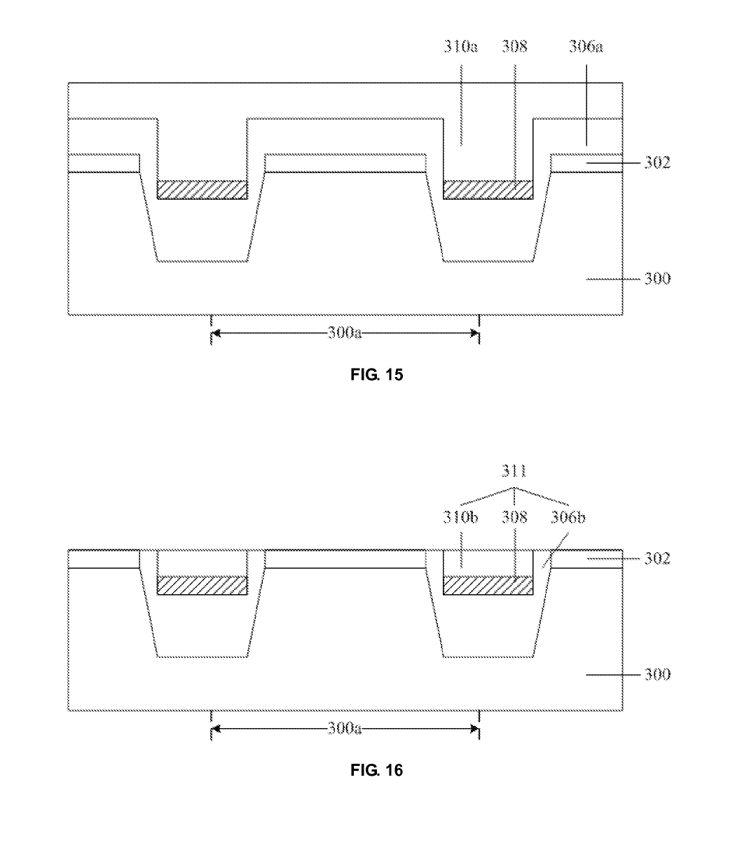

In Step 50 of FIG. 19 and referring to FIG. 15, a second barrier layer 310a can be formed on the entire surface of the structure shown in FIG. 14, e.g., on surfaces of the first barrier layer 306a and the light absorption layer 308. In one embodiment, the second barrier layer 310a can be formed to fill the isolation trench having the light absorption layer 308 at the bottom and having the first barrier layer 306a on the sidewalls. A portion of the second barrier layer 310a that is formed in the isolation trench can have a top surface no lower than the top surface of the blocking layer 302. In one embodiment, material(s) used for the second barrier layer 310a can be silicon oxide with a thickness of about 250 nm to about 1000 nm. The second barrier layer 310a can be formed by a chemical vapor deposition process.

In Step 60 of FIG. 19 and referring to FIG. 16, a planarization process (e.g., a CMP) can be conducted to planarize the structure shown in FIG. 15 to form a planarized structure. For example, portions of the first barrier layer 306a and the second barrier layer 310a can be removed to expose the blocking layer 302, the first barrier layer 306b, and the second barrier layer 310b. The planarized structure shown in FIG. 16 can then have an isolation structure 311 formed by the first battier layer 306b, the light absorption layer 308, and the second barrier layer 310b.

As shown, the first barrier layer 306b and the second barrier layer 310b are used as barrier layers for the isolation structure 311. The light absorption layer 308 is separated by the first barrier layer 306b from the semiconductor substrate 300 to avoid direct contact between the semiconductor substrate 300 and the light absorption layer 308 without affecting isolation effect of the isolation structure 311.

In various embodiments, light incident on the second barrier layer 310b can be absorbed by the light absorption layer 308. For light incident on the first barrier layer 306b, the amount of incident light entered the first barrier layer 306b can be controlled having a relatively small amount due to controllable distances between the light absorption layer 308 and the substrate 300. For example, at a horizontal direction, sidewalls of the light absorption layer 308 has a desired short distance to the interface between the first barrier layer 306b and the semiconductor substrate 300. In addition, a distance between the top surface of the light absorption layer 308 and the top surface of the semiconductor substrate 300 is sufficiently short.

The light incident on the first barrier layer 306b may be reflected at the interface between the first barrier layer 306b and the semiconductor substrate 300. Such reflected light from the interface can be absorbed by the light absorption layer 308. As such, the light absorption layer 308 formed between the first barrier layer 306b and the second barrier layer 310b can effectively prevent the incident light from entering the barrier layer(s) and prevent the reflected light reflected at the interface between the first barrier layer 306b and the semiconductor substrate 300 from exiting from the top surface of the barrier layer(s). Undesired excessive exposure of the PR layer on the semiconductor substrate 300 can then be eliminated in the subsequent processes.

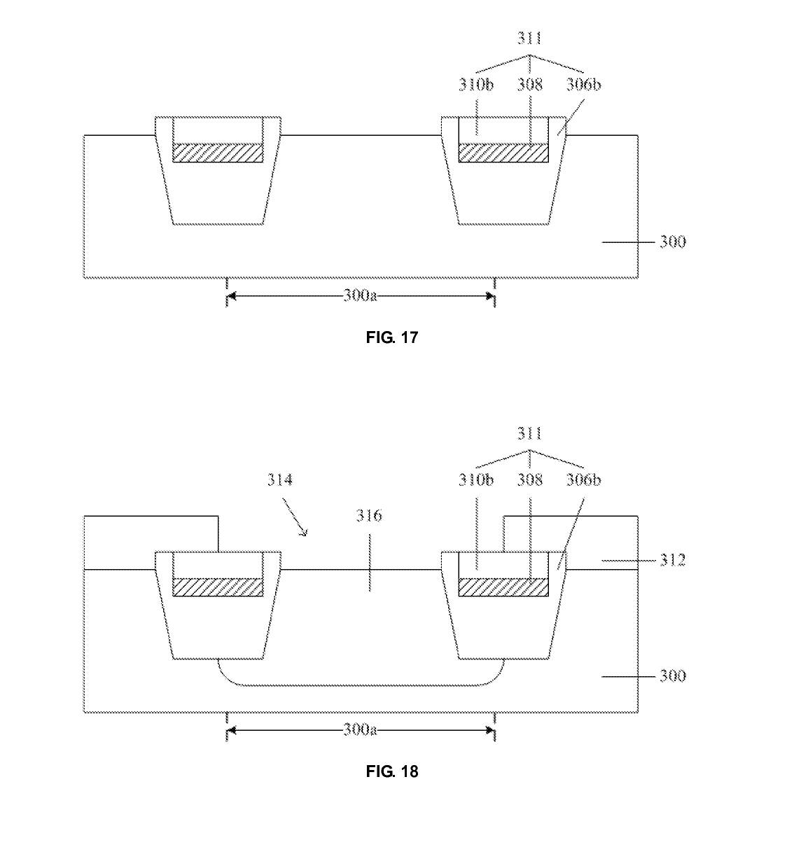

In Step 70 of FIG. 19 and referring to FIG. 17, the blocking layer 302 can be removed. In Step 80 of FIG. 19 and referring to FIG. 18, the patterned PR layer 312 containing a photolithographic pattern 314 can be formed over the semiconductor substrate 300 and the isolation structure 311, to expose the active region 300a. Processes for removing the blocking layer 302 and for forming the patterned PR layer 312 can be the same as or similar to corresponding processes as depicted in FIGS. 9-12.

Because the light absorption layer 308 can absorb the light entering the top surfaces of the first barrier layer 306b and the second barrier layer 310b, and the reflected light from the interface between the first barrier layer 306b and the semiconductor substrate 300, the formed photolithographic pattern 314 can thus have dimensions as originally designed.

In some embodiments, the light absorption layer (208a, 208b, and/or 308) can be a substrate reflectivity reduction layer for the photolithography process to reduce reflectivity from the substrate (200 and/or 300) and from the interface between the substrate and the first barrier layer (206a/b and/or 306a/b). The light absorption layer can also be used as an isolation layer in the isolation structure. For example, the light absorption layer can include a dielectric anti-reflective coating (DARC) to reduce substrate reflectivity for the subsequent ion implantation level lithography. In various embodiments, the DARC layer can be nitrogen-free. Of course, the formation method, material used, layer thickness, refractive index, extinction coefficient, the absorbed light wavelength, etc. for the exemplary DARC layer can be adjustable, for example, to minimize the reflectivity from the interface.

Still in FIG. 18, an ion implantation can be performed to form a well region 316 in the active region 300a using the patterned PR layer 312 as a mask. The process for forming the well region 316 can be the same as the process for forming the well region 216 as discussed above. The photolithographic pattern 314 in the patterned PR layer 312 can have dimensions as originally designed, which allows the well region 316 to be formed having dimensions as originally designed for the well region. Device performance of the subsequently-formed semiconductor device is improved.

In various embodiments, the light absorption layer (208a, 208b, and/or 308) or the DARC layer can also be used for other ion implantation level lithography, e.g., in a post-gate process for ion implantation, in addition to being used for the exemplary well formation, e.g., a pre-poly well implantation lithography.

In certain embodiments, material(s) used for the light absorption layer (208a, 208b, and/or 308) can be silicon nitride, silicon oxynitride, silicon oxycarbide, and/or any suitable materials. The light absorption layer can have an refractive index of about 1.5 to about 2.5 and an extinction coefficient of about 0.3 to about 2; and can absorb light with a wavelength of about 193 nm to about 248 nm.

As disclosed herein, a semiconductor structure is provided. Referring back to FIG. 10, the semiconductor structure includes a semiconductor substrate 200, an isolation structure in the semiconductor substrate 200, and an active region 200a positioned between the neighboring isolation structures. The isolation structure 211 in the semiconductor substrate 200 includes a first barrier layer 206b, a second barrier layer 210b, and a light absorption layer 208b disposed between the first barrier layer 206b and the second barrier layer 210b. The top surfaces of the first barrier layer 206b and the second barrier layer 210b are not lower than the top surface of the semiconductor substrate 200. The light absorption layer 208b is separated from the semiconductor substrate 200 by the first barrier layer 206b. The light absorption layer 208b can absorb light incident on the first barrier layer 206b and the second barrier layer 210b, and can absorb light reflected from the interface between the first barrier layer 206b and the semiconductor substrate 200. The first barrier layer 206b and the second barrier layer 210b forms barrier layers of the isolation structure 211.

Various embodiments also provide another exemplary semiconductor structure. For example, referring back to FIG. 17, a semiconductor structure includes a semiconductor substrate 300, an isolation structure in the semiconductor substrate 300, and an active region 300a between the neighboring isolation structures in the semiconductor substrate. The isolation structure 311 in the semiconductor substrate 300 includes a first barrier layer 306b, a second barrier layer 310b, and a light absorption layer 308b disposed between the first barrier layer 306b and the second barrier layer 310b. Top surfaces of the first barrier layer 306b and the second barrier layer 310b are not lower than a top surface of the semiconductor substrate 300. The light absorption layer 308 is separated from the semiconductor substrate 300 by the first barrier layer 306b to absorb light entering the top surfaces of the first barrier layer 306b and the second barrier layer 310b and to absorb light reflected from the interface between the first barrier layer 306b and the semiconductor substrate 300. The first barrier layer 306b and the second barrier layer 310b forms barrier layers of the isolation structure 311.

In one embodiment, the light absorption layer 208b is positioned on the first barrier layer 206b over the bottom surface and sidewalls of the isolation structure 211 as shown in FIG. 10. In another embodiment, the light absorption layer 308b is positioned on the first barrier layer 306b over the bottom surface of the isolation structure 311 as shown in FIG. 17. Note that, the shape of the light absorption layer (208a, 208b, and/or 308) is not limited in accordance with various embodiments. Any other suitable shapes can be encompassed herein for the light absorption layer in addition to the light absorption layer as depicted in FIGS. 10-17, for absorbing light incident on the barrier layer(s) and reflected from the interface between the isolation structure and the semiconductor substrate.

In one embodiment, substrate reflectivity from the interface between the isolation structure and the substrate with edge distance effect can be reduced, while exposing the active area for ion implantation to form semiconductor devices as desired. In various embodiments, the disclosed methods can be used for ion implantation, e.g., for a pre-poly well implantation lithography, and/or a post-gate process.

Other applications, advantages, alternations, modifications, or equivalents to the disclosed embodiments are obvious to those skilled in the art.

What is claimed is:

1. A semiconductor structure comprising:
a semiconductor substrate including an isolation trench;
a first barrier layer disposed on a bottom surface and a sidewall of the isolation trench;
a light absorption layer disposed at least on a surface portion of the first barrier layer over the bottom surface of the isolation trench; and
a second barrier layer filling the isolation trench to form an isolation structure in the semiconductor substrate, wherein the isolation structure includes the first barrier layer, the light absorption layer, and the second barrier layer and has a top surface flushed with or over a top surface of the semiconductor substrate.

2. The structure of claim 1, wherein the light absorption layer is made of a material including silicon nitride, silicon oxynitride, or silicon oxycarbide.

3. The structure of claim 1, wherein the light absorption layer has a refraction index of about 1.5 to about 2.5 and an extinction coefficient of about 0.3 to about 2, and absorbs light having a wavelength of about 193 nm to about 248 nm.

4. The structure of claim 1, wherein the light absorption layer is positioned between the first barrier layer and the second barrier layer.

5. The structure of claim 1, wherein the light absorption layer is disposed on the surface portion of the first barrier layer over the bottom surface of the isolation trench.

6. The structure of claim 1, wherein the light absorption layer is disposed on the first barrier layer and over the bottom surface and the sidewall of the isolation trench.

7. A method of forming a semiconductor structure comprising:
forming an isolation trench in a semiconductor substrate;
forming a blocking layer on a surface of the semiconductor substrate to expose the isolation trench;
forming a first barrier layer on a bottom surface and a sidewall of the isolation trench and on the blocking layer;
forming a light absorption layer at least on a surface portion of the first barrier layer over the bottom surface of the isolation trench; and
forming a second barrier layer to fill the isolation trench to form an isolation structure in the semiconductor substrate, wherein the second barrier layer has a top surface flushed with or over a top surface of the semiconductor substrate.

8. The method of claim 7, further including a planarization process to expose the blocking layer on the semiconductor substrate, the first barrier layer, the light absorption layer, and the second barrier layer.

9. The method of claim 8, further including removing the blocking layer to expose the semiconductor substrate.

10. The method of claim 7, wherein the light absorption layer is formed on an entire surface of the first barrier layer, the first barrier layer being formed on the bottom surface and the sidewall of the isolation trench and on the blocking layer.

11. The method of claim 7, wherein the light absorption layer is formed to absorb light incident on the top surface of the isolation structure and to absorb light reflected at an interface between the first barrier layer and the semiconductor substrate.

12. The method of claim 7, wherein the light absorption layer is formed on the surface portion of the first barrier layer over the bottom surface of the isolation trench, wherein the light absorption layer has a top surface lower than the top surface of the semiconductor substrate.

13. The method of claim 12, wherein the light absorption layer is formed such that a first distance, between the light absorption layer and an interface between the first barrier layer and the semiconductor substrate, is sufficiently short at a horizontal direction, and a second distance, between the top surface of the light absorption layer and the top surface of the semiconductor substrate, is sufficiently short, to reduce an amount of incident light entering the first barrier layer.

14. The method of claim 7, wherein the first barrier layer has a thickness of about 1 nm to about 50 nm, the light absorption layer has a thickness of about 5 nm to about 50 nm, and the second barrier layer has a thickness of about 250 nm to about 1000 nm.

15. The method of claim 7, further including using a chemical vapor deposition process to form each of the first barrier layer, the light absorption layer, and the second barrier layer.

16. The method of claim 7, wherein each of the first barrier layer and the second barrier layer is made of a material including silicon oxide.

17. The method of claim 7, wherein the light absorption layer is made of a material including silicon nitride, silicon oxynitride, or silicon oxycarbide.

18. The method of claim 7, wherein the light absorption layer has a refractive index of about 1.5 to about 2.5 and an extinction coefficient of about 0.3 to about 2; and
absorbs a light wavelength of about 193 nm to about 248 nm.

19. The method of claim 7, wherein the blocking layer is made of a material including silicon nitride.

20. The method of claim 7, further including forming an oxide padding layer on the bottom surface and the sidewall of the isolation trench prior to forming a first barrier layer.
